(19) United States
(12) Patent Application Publication
(10) Pub. No.: US 2007/0048548 A1
(43) Pub. Date: Mar. 1, 2007

(54) Organic light emitting device and manufacturing method thereof

(76) Inventors: Tae-Whan Kim, Seoul (KR); Young-Bae Yoon, Gunsan-si (KR)

Correspondence Address: CANTOR COLBURN, LLP, 55 GRIFFIN ROAD SOUTH, BLOOMFIELD, CT, 06002, US

(21) Appl. No.: 11/507,778

(22) Filed: Aug. 22, 2006

(30) Foreign Application Priority Data
Aug. 23, 2005 (KR) 10-2005-0077275

(51) Int. Cl. H01L 51/54; H01L 51/52

(52) U.S. Cl. 428/690; 428/917; 428/212; 313/504; 313/506; 427/66

(57) ABSTRACT

A hole blocking layer, having a multiple hetero-structure such that materials, each with a different doping density, are stacked repeatedly, is formed between a hole transport layer and an electron transport layer. An organic light emitting device and its manufacturing method can enhance luminous efficiency and color stability having the abovementioned hole blocking layer.

This application claims priority to Korean Patent Application No. 10-2005-0077275, filed on Aug. 23, 2005, and all the benefits accruing therefrom under 35 U.S.C. § 119, the contents of which in its entirety are herein incorporated by reference.

### BACKGROUND OF THE INVENTION

(a) Field of the Invention

The present invention relates to an organic light emitting device and manufacturing method thereof.

(b) Description of the Related Art

Recently, as the display size of display devices increases, demand for flat panel display devices that occupy a smaller space is correspondingly increasing. Techniques for producing an organic light emitting device, one type of flat panel display device, has also been rapidly increasing.

Charge injection characteristics on an interface between an organic light emitting material and an electrode significantly affects the quantum efficiency and the operational voltage of the light emitting device using those materials, and also plays a critical role in the lifespan of such a light emitting device. Therefore, research regarding organic light emitting devices generally focuses on the interfacial charge injection characteristics of the device in order to improve the lifespan and efficiency thereof.

Regarding carrier mobility in an organic material, generally, holes (the absence of an electron from an otherwise full valence band of an atom) move more easily than electrons because of ionization potential and electron affinity. The result of this imbalance in mobility is that if a similar number of holes and electrons are formed on either end of the organic matter, the faster moving holes will pass through much of the organic matter before colliding with, and subsequently annihilating, an electron. Because electrons are not easily moved within the organic matter, greater numbers of excitons (a bound state of an electron and an electron hole) are created near the cathode where the electrons originate. However, when the annihilation of the electron and the hole occurs near the electrodes no light is emitted from the exciton; a result that is sometimes called a non-radiative emission. This leads to degraded quantum efficiency of the organic light emitting device. The quantum efficiency is a measure of what percentage of annihilations between holes and electrons result in radiative emission.

Therefore, because hole mobility is inherently hundreds, or even thousands, of times faster than electron mobility, in order to allow holes and electrons to be re-combined in an emission layer, the hole mobility must be lowered to maximize luminous efficiency.

In order to lower the hole mobility so that excitons are created in the emission layer, a hole blocking layer and an exciton blocking layer are typically inserted at the end of the emission layer furthest from the anode. However, such a configuration has a negative influence on the injection and mobility characteristics of not only the holes but also the electrons and this results in a reduction of a life span of the device.

In addition, the emission layer of existing organic light emitting devices either has a single-layer or a multi-layer structure which is relatively narrow and has a correspondingly narrow light emitting region. The result of which is that the devices have a low luminous efficiency, and it is difficult to obtain colors which remain stabilized with respect to an increase in an applied current. In this sense, existing light emitting devices need to be improved.

### BRIEF SUMMARY OF THE INVENTION

It is an aspect of the present invention to provide an organic light emitting device with a layer structure and a manufacturing method thereof, having advantages of accomplishing high luminous efficiency and obtaining stabilized colors.

An exemplary embodiment of the present invention provides an organic light emitting device including an anode formed on a substrate, a hole transport layer formed on the anode and comprising a hole transport material, a hole blocking layer formed on the hole transport layer and including the hole transport material and a light emitting material, an electron transport layer formed on the hole blocking layer, and a cathode formed on the electron transport layer. The hole blocking layer has a multiple hetero-structure in which a first mixture layer includes the hole transport material and the light emitting material in a mixture according to a first ratio and a second mixture layer including the hole transport material and the light emitting material in a mixture according to a second ratio different than the first ratio are repeatedly stacked.

### BRIEF DESCRIPTION OF THE DRAWINGS

The above and other features and advantages of the present invention will become more apparent by describing in more detail exemplary embodiments thereof with reference to the attached drawings, in which:

FIG. 1 is a schematic diagram showing an exemplary embodiment of an organic light emitting device having a layer structure according to the present invention;

FIG. 2 is a schematic diagram showing an energy band of the exemplary embodiment of an organic light emitting device with a new layer structure according to the present invention;

FIG. 3 is a drawing showing the composition of an exemplary embodiment of an organic light emitting device according to the present invention;

FIG. 4 is a graph showing measured current density corresponding to an increase in voltage for an exemplary embodiment of the organic light emitting device according to the present invention and two comparative examples;

FIG. 5 is a graph showing measured luminance corresponding to an increase in voltage for an exemplary embodiment of the organic light emitting device according to the exemplary embodiment of the present invention and two comparative examples;

FIG. 6 is a graph showing luminous efficiency corresponding to an increase in current density for an exemplary embodiment of the organic light emitting device according the present invention and two comparative examples; and

FIG. 7 is a graph showing color coordinates of the exemplary embodiment of the organic light emitting device according to the present invention and two comparative examples.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

An exemplary embodiment of the present invention will hereinafter be described in detail with reference to the accompanying drawings.

A driving principle and a structure of an exemplary embodiment of an organic light emitting device are described below.

When a driving voltage is applied to an anode and a cathode, holes and electrons transfer toward an emission layer to generate excitons in the emission layer. As the energy states of the excitons fall from an excited state to a ground state, photons emitted therefrom. The photons have an energy equal to the difference between the excited state and the ground state. In the emission layer that energy difference produces photons with energy corresponding to visible light. Accordingly, a plurality of photons emitted from a plurality of emission layers may be used to display an image. When the photons pass through a transparent anode electrode that type of display is called a bottom-emission type display; when the photons instead pass through a transparent cathode electrode that type of display is called a top-emission type display.

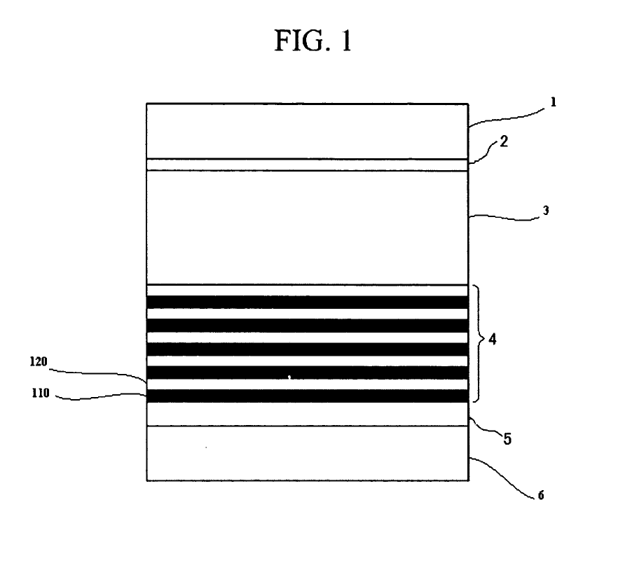

FIG. 1 is a schematic diagram of an exemplary embodiment of an organic light emitting device with a layer structured according to the present invention. The anode 6, which is used for hole injection is made of a transparent conductive oxide such as indium tin oxide (“ITO”) or indium zinc oxide (“IZO”) that allows light to be emanated to the outside and has a high work function. The anode 6 may have a thickness of about 150 nm.

A hole transport layer 5 may include N,N′-diphenyl-N,N′-bis (1,1′-biphenyl)-4,4′-diamine(“NPB”), N,N′-diphenyl-N,N′-bis(3-methylphenyl)-(1,1′-biphenyl)-4,4′-diamine(“TPD”), 11,11,12,12-tetracyano-9,10-anthraquinodimethane (disclosed in Synth. Met. 85, 1267 (1997)), a distyryl triphenylene compound (disclosed in Synth. Met. 91, 257 (1997)), 1,3,5-tris-(N,N-bis-(4,5-methoxy-phenyl)-aminophenyl)-benzene (disclosed in Synth. Met.111-112, 263 (2000)), N,N′-bis(4-(2,2-diphenylethenyl)-phenyl)-N,N′-di(p-tolyl)-bendidine(“DPS”) and its derivatives, and 4,4′,4″-tri(diphenylamino)triphenylamine(“TDATA”) and its derivatives, etc., and can be deposited with a thickness of about 5 nm to about 15 nm.

A hole blocking layer 4 has a multiple hetero-structure, meaning that two kinds of mixture layers are alternately stacked on one another to form the hole blocking layer 4. The two kinds of mixture layers are made of the hole transport layer material as mentioned above and a light emitting material. The difference between the two mixture layers lies in the different ratio of the two materials in each layer. That ratio will be referred to as a mixing ratio. According to one exemplary embodiment, there are three to six mixture layers alternately stacked on one another. The hole blocking layer 4 traps holes using barriers owing to a difference in the highest occupied molecular orbital (“HOMO”) level between the hole transport layer material and the light emitting material. Essentially, a potential barrier corresponding to the energy difference between the HOMO levels of the two materials works to slow the mean velocity of the holes traveling through those layers. This layer does not affect the mean velocity of the electrons, therefore the two mobilities (hole mobility and electron mobility) become more balanced and excitons are more likely to be formed in the emission layer where they may emit photons.

The hole blocking layer 4 also serves as the emission layer. If the two kinds of mixture layers are alternatingly stacked merely one or two times, it is difficult to obtain emitted light with color coordinates in the yellow region of a CIE 1931 color space (a tool for defining the perception of color). However, if the two kinds of mixture layers of the hole transport layer material and the light emitting material are stacked seven or more times, a turn-on voltage increases, which can make the device fail to operate properly.

The organic light emitting device having the hole blocking layer 4 can enhance luminous efficiency by effectively lowering hole mobility, and although the current density increases, the organic light emitting device can exhibit stabilized color coordinate characteristics to obtain light with high efficiency.

The hole transport material can be selected from the above-stated materials. The light emitting material can be selected from the group consisting of 5,6,11,12-tetraphenylnaphthacene(Rubrene), perylene, 4-dicyano-methylene-2-methyl-6-4-dimethylami-nostyryl-4H-piran(“DCM1”), and 4-(dicyanomethylene)-2-(1-propyl)6-methyl 4H-pyran(“DCJTB”).

The electron transport layer 3 includes at least one selected from the group consisting of tris-(8-hydroxyquinoline)aluminum(“Alq3”), 3-(4-biphenylyl)-4-phenyl-5-(4-tert-butylphenyl)-1,2,4-triazole(“TAZ”), 2-(4-biphenylyl)-5-(4-tert-butylphenyl)-1,3,4-oxadiazole(“PBD”), bis(10-hydroxybenzo[h]quinolinato)beryllium(“Bebq2”), 2,2,2′-(1,3,5-benzenetriol)tris-[1-phenyl-1H-benzimidazole](“TPBI”), aluminum(III) bis(2-methyl-8-quinolinato)4-phenylphenolate(“Balq”), 2,9-dimethyl-4,7-diphenyl-1,10-phenanthroline(“BCP”), and can be deposited with a thickness of about 50 nm to about 70 nm.

The electron injection layer 2 may be omitted. However if it is to be formed, a thin layer of LiF or lithium quinolate (“Liq”) may be used or an alkali metal or alkaline earth metal such as Li, Ca, Mg, or Sr, or other similar materials, may also be used to improve electron injection performance. According to a first exemplary embodiment of the present invention, Liq is formed with a thickness of about 2 nm.

A cathode 1 may be made of material having a small work function such as Ca, Mg, or Al, or other similar materials. Ideally the work function of the cathode corresponds to the energy level of the lowest unoccupied molecular orbital (“LUMO”).

In the first exemplary embodiment of the present invention, NPB is used as the hole transport layer material, and Rubrene is used as the light emitting material to fabricate a high efficiency organic light emitting device that operates in the yellow region of a CIE 1931 color space.

The structure of a first exemplary embodiment of an organic light emitting device according to the present invention is described as follows starting with the anode and working towards the cathode with “/” marks indicating boundaries between layers. The structure of the current exemplary embodiment is ITO/about 10 nm of NPB/[about 3 nm of a 50% NPB:50% Rubrene mix by weight/about 5 nm of a 99% NPB:1% Rubrene mix by weight]/Alq3/about 2 nm of Liq/Al. This means that the hole blocking layer is formed of the mixedly deposited Rubrene and NPB and has a structure in which a layer with a weight ratio (NPB:Rubrene) of 1:1 and a thickness of 3 nm, and a layer with a weight ratio of 99:1 and a thickness of 5 nm, are stacked repeatedly five times (accordingly, the hole transport layer has a thickness of 10 nm and the hole blocking layer has a thickness of about 40 nm, totaling a thickness of about 50 nm).

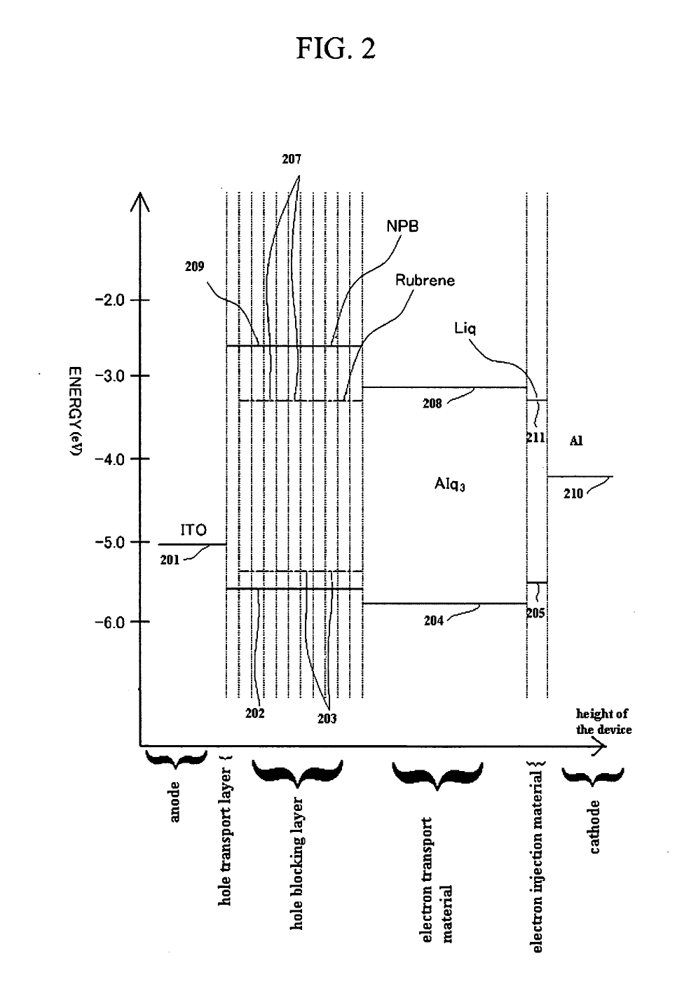

The structure of this first exemplary embodiment is shown in more detail in FIG. 2. FIG. 2 shows the cross section of the first exemplary embodiment of an organic light emitting device according to height, starting with the anode at the left side of the abscissa. FIG. 2 also displays the energy levels of the various materials, in eV, along the ordinate. The work function of the anode is shown by reference numeral 201. The HOMO of NPB, Rubrene, Alq3, and Liq are shown by 202, 203, 204 and 205 respectively. The LUMO of NPB, Rubrene, Alq₃, and Liq are shown by 209, 207, 208 and 211 respectively. The work function of the cathode is shown by reference numeral 210.

The structure of another exemplary embodiment of an organic light emitting device according to the present invention can be described as ITO/about 10 nm of NPB/[about 3 nm of a 50% NPB:50% Rubrene mix by weight/about 10.3 nm of a 99% NPB:1% Rubrene mix by weight]₃/Alq3/Liq/Al. This means that the hole blocking layer is formed of the mixedly deposited Rubrene and NPB and has a structure in which layers with a weight ratio (NPB:Rubrene) of 1:1 and a thickness of 3 nm and layers with a weight ratio of 99:1 and a thickness of 10.3 nm are stacked repeatedly three times (accordingly, the hole transport layer has a thickness of about 10 nm and the hole blocking layer has a thickness of about 40 nm, totaling a thickness of about 50 nm).

The structure of the another exemplary embodiment of an organic light emitting device according to the present invention can be described as ITO/about 10 nm of NPB/[about 3 nm of a 50% NPB:50% Rubrene mix by weight/about 7 nm of a 99% NPB:1% Rubrene mix by weight]₄/Alq3/Liq/Al. This means that the hole blocking layer is formed of the mixedly deposited Rubrene and NPB and has a structure in which a layer with a weight ratio (NPB:Rubrene) of 1:1 and a thickness of 3 nm and a layer with a weight ratio of 99:1 and a thickness of 7 nm are stacked repeatedly four times (accordingly, the hole transport layer has a thickness of about 10 nm and the hole blocking layer has a thickness of about 40 nm, totaling a thickness of about 50 nm).

The structure of yet another exemplary embodiment of an organic light emitting device according to the present invention can be described as ITO/ about 10 nm of NPB/[about 3 nm of a 50% NPB:50% Rubrene mix by weight/ about 3.6 nm of a 99% NPB:1% Rubrene mix by weight]₆/Alq3/Liq/Al. This means that the hole blocking layer is formed of the mixedly deposited Rubrene and NPB and has a structure in which a layer with a weight ratio (NPB:Rubrene) of 1:1 and a thickness of 3 nm and a layer with a weight ratio of 99:1 and a thickness of 3.6 nm are stacked repeatedly six times (accordingly, the hole transport layer has a thickness of about 10 nm and the hole blocking layer has a thickness of about 40 nm, totaling a thickness of about 50 nm).

The thickness of the hole transport layer and the hole blocking layer may vary depending on the type of stacked material and the number of stacked layers, and it is noted that high efficiency may be obtained when the total thickness of the layers is about 40 nm to about 50 nm and that the maximum efficiency may be obtained when the total thickness of the layers is about 50 nm.

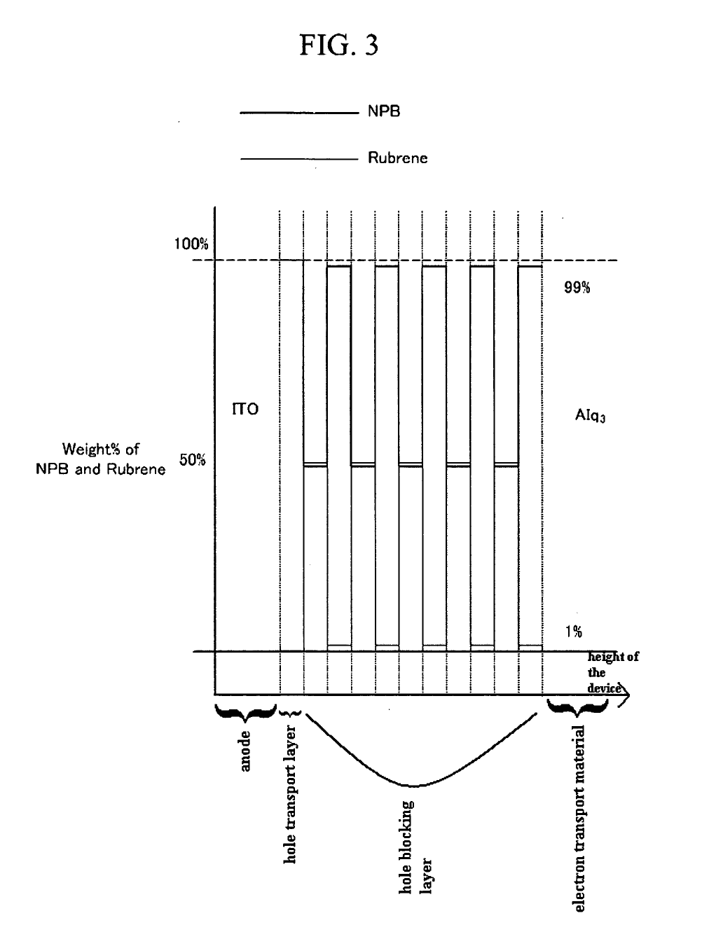

According to a different aspect of the present invention, an exemplary embodiment of a method for manufacturing the organic light emitting device can be presented as follows. With reference to FIGS. 1 and 2, the hole transport layer 5 is deposited on the anode 6. The light emitting material and the hole transport layer material, each with the mixing ratio of NPB and Rubrene as shown in FIG. 3, are deposited repeatedly three to six times onto the hole transport layer 5 in order to form the hole blocking layer 4. Next, the electron transport layer 3, the electron injection layer 2, and the anode 1 are sequentially stacked on the resulting structure to complete the organic light emitting device. In the organic light emitting device manufactured according to the exemplary embodiment of the method of the present invention, the hole blocking layer has a structure in which the hole transport layer material and the light emitting material are stacked repeatedly, thereby the luminous efficiency can be enhanced. Additionally by varying the type, the number, the position, and the thickness of the multiple hetero-layers the wavelength of the emitted light may be controlled and color purity may be improved.

An exemplary embodiment of a method for manufacturing the organic light emitting device according to an exemplary embodiment of the present invention will now be described with reference to the accompanying drawings. The present invention is not limited to the following exemplary embodiments, and can be modified in various manners by a person with ordinary skill in the art within the scope of the present invention.

<Exemplary Embodiment 1>

Fabrication 1 of the Organic Light Emitting Device

<1-1>Fabrication of the Anode

An ITO thin film is deposited on a glass substrate with a thickness of 150 nm and surface resistance of 30Ω/□

<1-2>Fabrication of the Hole Transport Layer

An NPB layer with a thickness of 10 nm was deposited while sustaining a vacuum atmosphere of about 10⁻⁷ to about 10⁻⁹ Torr therefor.

In this case, the growth speed was sustained at about 0.1 nm/sec. to grow a high quality thin film.

<1-3>Fabrication of the Hole Blocking Layer

Rubrene was mixedly deposited with NPB such that mixing ratio (by weight) of Rubrene was 50% in a vacuum atmosphere of 10⁻⁷-10⁻⁹ Torr to form a layer 110 with a thickness of 3 nm, and subsequently Rubrene was mixedly deposited with NPB such that the mixing ratio of Rubrene was 1% to form a layer 120 with a thickness of 5 nm. The two layers were deposited repeatedly five times.

<1-4>Fabrication of the Electron Transport Layer

Alq3 was vacuum-deposited with a thickness of 50 nm on the fabricated hole blocking layer to form the electron transport layer. The vacuum atmosphere of about 10⁻⁷-10⁻⁹ Torr was sustained and the growth speed was sustained at about 0.1 nm/sec. to grow a high quality thin film.

<1-5>Fabrication of the Liq Electron Injection Layer and the Cathode

With the vacuum atmosphere of about 10⁻⁷-10⁻⁹ Torr sustained and the growth speed of about 0.1 nm/sec. sustained, Liq was deposited with a thickness of 2 nm, and then Al was deposited with a thickness of 100 nm to form the cathode.

<Exemplary Embodiment 2>

Fabrication 2 of an Organic Light Emitting Device

An organic light emitting device was fabricated in the same manner as in Exemplary Embodiment 1, except th at a layer 110 was deposited with a thickness of 3 nm and a layer 120 was deposited with a thickness of 10.3 nm, and the two layers were deposited twice to form a hole blocking layer.

<Exemplary Embodiment 3>

Fabrication 3 of an Organic Light Emitting Device

An organic light emitting device was fabricated in the same manner as in Exemplary Embodiment 1, except that a layer 110 was deposited with a thickness of 3 nm and a layer 120 was deposited with a thickness of 7 nm, and the two layers were deposited repeatedly three times to form a hole blocking layer.

<Exemplary Embodiment 4>

Fabrication 4 of an Organic Light Emitting Device

An organic light emitting device was fabricated in the same manner as in Exemplary Embodiment 1, except that a layer 110 was deposited with a thickness of 3 nm and a layer 120 was deposited with a thickness of 3.6 nm, and the two layers were deposited repeatedly five times to form a hole blocking layer.

### Comparison Example 1

Fabrication 1 of an Organic Light Emitting Device

A basic device including an emission layer in which Rubrene was doped at 1% in Alq3 was fabricated (Structure I: ITO/50 nm of NPB/10 nm of a 99% Alq3: 1% Rubrene mix by weight/50 nm of Alq3/Liq 2 nm/Al).

### Comparison Example 2

Fabrication 2 of an Organic Light Emitting Device

An organic light emitting device has the same basic layer structure as that of the exemplary embodiments of the present invention, but it has a multiple hetero-structure in which materials of a hole blocking layer were not mixedly deposited but were alternately stacked (Structure II: ITO/10 nm of NPB/[3 nm of Rubrene/5 nm of NPB]₅/Alq3/Liq/Al). In detail, the hole blocking layer has a structure in which Rubrene and NPB are stacked alternately five times, and the hole transport layer has a thickness of 10 nm and the hole blocking layer has a thickness of 40 nm, totaling a thickness of 50 nm.

### Experimental Example 1

Comparison of Efficiency of the Organic Light Emitting Device

<1-1>Measurement of a Current-Density versus Voltage of the Organic Light Emitting Device

In order to compare the devices of Comparative Examples 1 and 2 and the organic light emitting device (Structure III) according to the first exemplary embodiment of the present invention, the current density-voltage was measured by units of 0.5 V from 0 to 15 V by using a Source-Measure Unit, model 236, manufactured by Keithley Instruments Inc. (hereinafter, “the Keithley”).

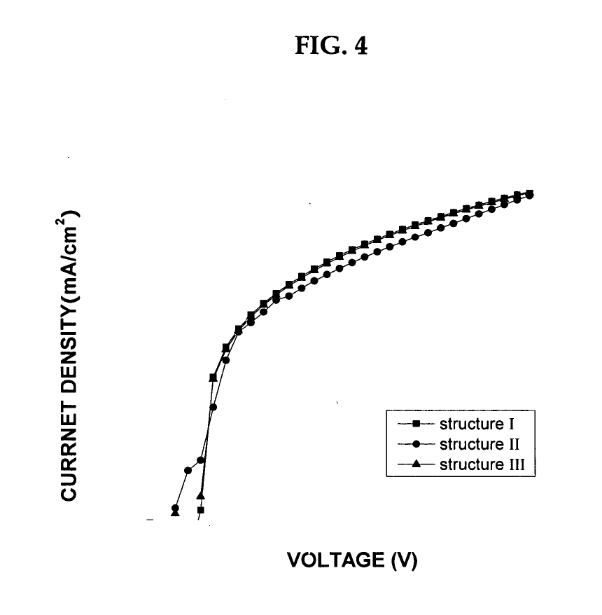

FIG. 4 is a graph showing the results, in which it is noted that turn-on voltages for starting illumination of the structures I, II, and III were all 3.5 V. The current density of the first exemplary embodiment of an organic light emitting device of the present invention was slightly lower compared with the device of the structure I. This was determined to be case because, since the hole blocking layer of the organic light emitting device of the present invention has a multiple hetero-structure to lower the hole mobility, holes were restrained in the well structure of the light emitting region and thus the mobility was slightly lower than that of the structure I which had unrestrained hole mobility.

<1-2>Measurement of a Luminance-Voltage of the Organic Light Emitting Device

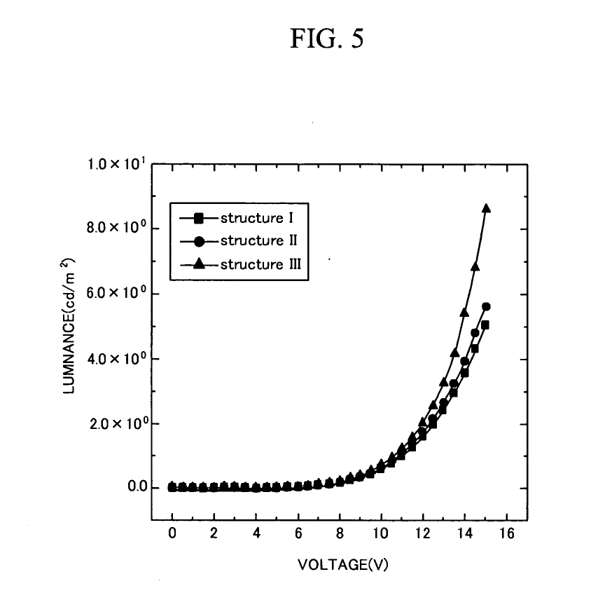

With voltages of 0 to 15 V applied to the anode and the cathode of the organic light emitting device having the two structures by using the Keithley, luminance was measured with a luminance meter, particularly the Chroma Meter CS-100A manufactured by Konica Minolta, within a black box. FIG. 5 shows the measured values as a function of voltage. As a result, the device with the structure I had a luminance of 5,050 cd/m² at 15 V, the device with the structure II had a luminance of 5,600 cd/m²at 15 V, and the device with the structure III had a luminance of 8,640 cd/m² at 15 V. Thus, it can be noted that the device with the structure III had the highest luminance as the hole mobility was lowered to form an optimum balance with electrons.

<1-3>Measurement of Efficiency versus Current Density of the Organic Light Emitting Device

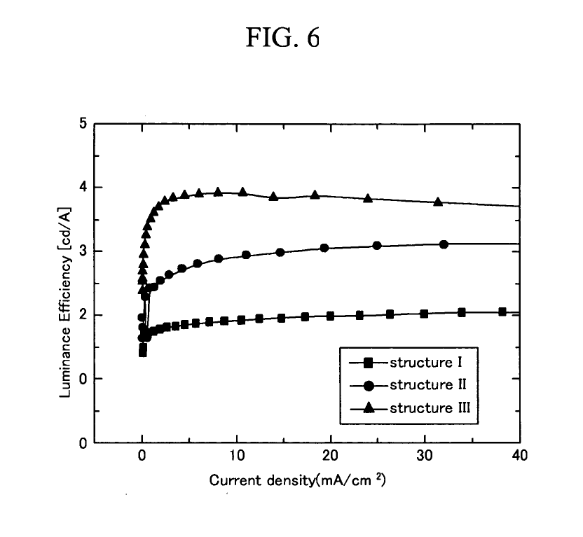

FIG. 6 is a graph showing current density to current efficiency based on the measured values in the Experimental Examples 1-1 and 1-2. The device with the structure I shows a uniform current efficiency of about 1.9 cd/A above 10 mA/cm², the device with the structure II shows a current efficiency of about 2.9 cd/A above 10 mA/cm², and the device with the structure III shows a high current efficiency of about 3.9 cd/A above 10 mA/cm². Accordingly, compared with the comparative organic light emitting device without a hole blocking layer and the comparative device including the hole blocking layer formed with sharp heterojunctions, the exemplary embodiment of an organic light emitting device of the present invention has higher current efficiency. Moreover, even when the current increases, its efficiency is not significantly degraded.

<1-4>Comparison of Color Coordinates

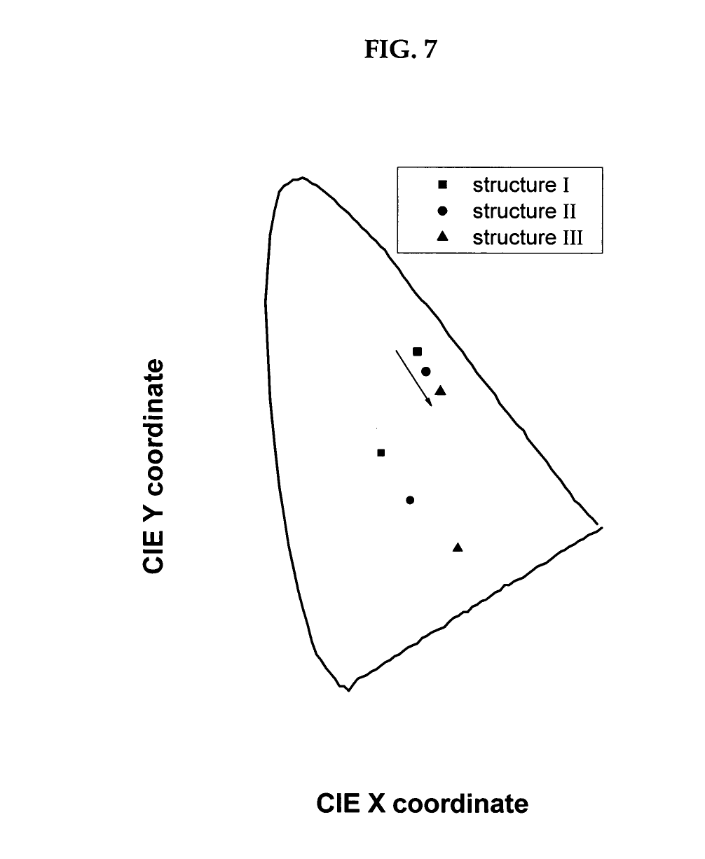

FIG. 7 shows color coordinates of the three organic light emitting devices measured at 15 V. The device with the structure I showed CIE 1931 (0.34, 0.55), the device with the structure II showed CIE 1931 (0.35, 0.52), while the device with the structure III showed CIE 1931 (0.39, 0.49), so it can be understood that the device of the present invention can be operated in the further stabilized yellow region. As described above, the organic light emitting device according to the present invention has advantages such that since the hole blocking layer has the multiple hetero-structure, the luminous efficiency can be enhanced, and in addition, since the light emitting wavelength range can be controlled by varying the type, the number, the position, and the thickness of the multiple hetero-layers, the light emitted therefrom may be controlled so that a yellow color with a high degree of purity may be achieved.

While this invention has been described in connection with what is presently considered to be practical exemplary embodiments, it is to be understood that the present invention is not limited to the disclosed exemplary embodiments, but, on the contrary, is intended to cover various modifications and equivalent arrangements included within the spirit and scope of the appended claims.

What is claimed is:

1. An organic light emitting device comprising:
an anode formed on a substrate;
a hole transport layer formed on the anode and comprising a hole transport material;
a hole blocking layer formed on the hole transport layer and comprising the hole transport material and a light emitting material;
an electron transport layer formed on the hole blocking layer; and
a cathode formed on the electron transport layer,
wherein the hole blocking layer has a multiple hetero-structure in which a first mixture layer comprising the hole transport material and the light emitting material in a mixture according to a first ratio and a second mixture layer comprising the hole transport material and the light emitting material in a mixture according to a second ratio different than the first are repeatedly stacked.

2. The device of claim 1, wherein the light emitting material comprises at least one selected from the group consisting of 5,6,11,12-tetraphenylnaphthacene (Rubrene), perylene, 4-dicyano-methylene-2-methyl-6-4-dimethylami-nostyryl-4H-piran(DCM1), and 4-(dicyanomethylene)-2-(1-propyl)6-methyl 4H-pyran(DCJTB).

3. The device of claim 1, wherein the hole transport material comprises at least one of N,N′-diphenyl-N,N′-bis(1,1′-biphenyl)-4,4′-diamine(NPB) and N,N′-diphenyl-N,N′-bis(3-methylphenyl)-(1,1′-biphenyl)-4,4′-diamine(TPD).

4. The device of claim 1, wherein the first ratio of the hole transport material and the light emitting material is about 50:50 wt % and the second ratio of the hole transport material and the light emitting material is about 99:1 wt %.

5. The device of claim 1, wherein the sum of the thickness of the hole transport layer and the thickness of the hole blocking layer is about 40 nm to about 50 nm.

6. The device of claim 1, wherein the first mixture layer and the second mixture layer are stacked repeatedly three to six times.

7. A method for manufacturing an organic light emitting device, comprising:
forming an anode on a substrate;
forming a hole transport layer on the anode;
forming a hole blocking layer on the hole transport layer;
forming an electron transport layer on the hole blocking layer; and,
forming a cathode on the electron transport layer,
wherein, the forming of the hole blocking layer comprises repeatedly stacking a first mixture layer and a second mixture layer, wherein the first mixture layer comprises a light emitting material and a hole transport material according to a first ratio and a second mixture layer comprises a light emitting material and a hole transport material according to a second mixing ratio different than the first.

8. The device of claim 7, wherein the first ratio of the hole transport material and the light emitting material is about 50:50 wt % and the second ratio of the hole transport material and the light emitting material is about 99:1 wt %.
